(19) United States
(12) Patent Application Publication
(10) Pub. No.: US 2006/0056537 A1
(43) Pub. Date: Mar. 16, 2006

(54) Multiple qam modulation device, multiple qam demodulation device, and communication method using gain-difference multiplexing

(76) Inventor: Kazutomo Hasegawa, Kawasaki (JP)

Correspondence Address: JENKENS & GILCHRIST, PC, 1445 ROSS AVENUE, SUITE 3200, DALLAS, TX, 75202, US

(21) Appl. No.: 10/535,549

(22) PCT Filed: Nov. 10, 2003
(86) PCT No.: PCT/JP03/14248

§ 371 Date: May 18, 2005

(30) Foreign Application Priority Data
Nov. 19, 2002 (JP) 2002-335020

(51) Int. Cl. H04L 27/36; H03D 3/00

(52) U.S. Cl. 375/298; 375/322

(57) ABSTRACT

A multiplexing QAM apparatus according to the invention is provided with a QAM unit and a modulated waves combining unit. The QAM unit generates plural QAM-modulated waves by QAM-modulating plural input data (including a case of data obtained by dividing a single piece of input data) using a common carrier frequency. The modulated waves combining unit generates a multiplexed QAM-modulated wave by combining the plural QAM-modulated waves together after giving a gain difference to them. In doing so, the modulated waves combining unit gives the gain difference to the plural QAM-modulated waves before the synthesis so that no overlap will occur in a symbol position arrangement of the synthesized multiplexed QAM-modulated wave.

### TECHNICAL FIELD

The present invention relates to transmission of digital data. More specifically, the invention relates to multiplexing of QAM (Quadrature Amplitude Modulation).

### BACKGROUND ART

Among the conventional digital data modulation methods, the QAM method is known.

The QAM method is a modulation method in which the phase and the amplitude of a carrier are varied simultaneously by adding two orthogonal ASK (amplitude shift keying) waves together. The QAM method can realize multi-valued signal transmission. For example, if it is assumed that there are n common-mode-component signal levels and m orthogonal-mode-component signal levels, a (n x m)-valued signal can be transmitted at one time by combining the two kinds of signal levels.

The DMT method is known that is a modulation method in which QAM-modulated waves as mentioned above are frequency-multiplexed.

The CAP method etc. are also known that are modulation methods based on the above QAM method.

The following Patent document 1 is known as a conventional technique that is improved in the symbol position arrangement (constellation) of the QAM method. In Patent document 1, the degree of freedom in setting an inter-symbol distance is increased by setting common-mode-component and orthogonal-mode-component amplitude levels nonlinearly.

Patent document 1: Japanese Unexamined Patent Application Publication No. Hei 8-79325

Incidentally, in the field of digital data transmission, faster transmission techniques are strongly desired. Accordingly, also in the QAM method, realization of an even higher degree of multi-valuing is demanded to make it possible to transmit a large amount of information at one time.

### DISCLOSURE OF THE INVENTION

An object of the present invention is therefore to provide a novel multiplexing technique for realizing multi-valuing in the above-described QAM method.

Another object of the invention is to provide a technique for increasing the degree of freedom of symbol position arrangement in the QAM method.

A further object of the invention is to provide a technique for efficiently demodulating a multiplexed QAM-modulated wave generated according to the invention.

The invention will be described below.

(1) A multiplexing QAM apparatus according to the invention is provided with a QAM unit and a modulated waves combining unit. The QAM unit generates a plurality of QAM-modulated waves by QAM-modulating a plurality of input data (including a case of data obtained by dividing a single piece of input data) using a common carrier frequency.

The modulated waves combining unit generates a multiplexed QAM-modulated wave by combining the plurality of QAM-modulated waves together after giving a gain difference to them. In doing so, the modulated waves combining unit gives the gain difference to the QAM-modulated waves before the synthesis so that no overlap will occur in a symbol position arrangement of the synthesized multiplexed QAM-modulated wave.

In this specification, this multiplexing method of the invention is called “differential gain multiplexing” to discriminate it from the conventional frequency multiplexing.

A specific example will be described below.

FIG. 1 shows an example of synthesis of a multiplexed QAM-modulated wave. In FIG. 1, a QAM-modulated wave M1 to be combined is a 16-valued QAM-modulated wave and the other QAM-modulated wave M2 is a 4-valued QAM-modulated wave.

The QAM-modulated waves M1 and M2 have the same carrier frequency. Therefore, the synthesis of the QAM-modulated waves M1 and M2 can be regarded as vector addition of symbol positions on the IQ constellation.

That is, in the case of FIG. 1, the 16 symbol positions of the QAM-modulated wave M1 and the four symbol positions of the QAM-modulated wave M2 are subjected to vector addition, whereby a multiplexed QAM-modulated wave MM having 64 (=16×4) new symbol positions is generated.

This synthesis has a problem that the symbol positions of the multiplexed QAM-modulated wave MM may coincide with each other in a certain situation and hence cannot be used for signal transmission.

The invention solves this problem by giving a gain difference to the QAM-modulated waves M1 and M2 to be combined. That is, the gain of the one QAM-modulated wave M2 is made relatively low, whereby the expanse of each symbol position of the multiplexed QAM-modulated wave MM is decreased and adjoining symbol positions are prevented from coincide with each other.

FIG. 1 is directed to a case that the symbol positions of the multiplexed QAM-modulated wave MM are arranged at regular intervals. However, a multiplexed QAM-modulated wave in which symbol positions have desired, different intervals can easily be generated by adjusting the gain difference, the symbol position arrangements, or the like before the synthesis.

FIG. 2 shows another example of synthesis. In this example, a QAM-modulated wave M3 is used instead of the QAM-modulated wave M2. The QAM-modulated wave M3 is such that a zero point (i.e., a state without a carrier) is added as a signal to the 4-valued QAM. Combining the QAM-modulated wave M3 including the zero point with the QAM-modulated wave M1 makes it possible to leave the symbol positions themselves of the QAM-modulated wave M1 in a multiplexed QAM-modulated wave MN. That is, a total of 80 symbol positions, which is the sum of 64 symbol positions obtained by the synthesis and the 16 symbol positions before the synthesis, appear in the multiplexed QAM-modulated wave MN.

As is understood from the above specific example, the multiplexing QAM apparatus according to the invention makes it possible to further increase the degree of freedom of symbol position arrangement while realizing a further increased level of multi-valuing of a QAM-modulated wave.

(2) It is preferable that the QAM unit gives a phase difference to at least two of the QAM-modulated waves.

A specific example will be described below.

FIG. 3 shows an example of synthesis of a multiplexed QAM-modulated wave in which a phase difference is employed. QAM-modulated waves M1 and M4 before synthesis has a phase difference θ between carriers. Combining such QAM-modulated waves M1 and M4 makes it possible to generate a multiplexed QAM-modulated wave MP shown in FIG. 3.

In the multiplexed QAM-modulated wave MP, by virtue of the phase difference θ that was employed before the synthesis makes, the symbol position arrangement can be given local inclinations as shown in FIG. 3.

As is understood from the above specific example, in the multiplexing QAM apparatus according to claim 2, local inclinations can be introduced in a symbol position arrangement, whereby symbol position arrangements that are more flexible than those so far realized can be realized easily.

(3) It is even preferable that the modulated waves combining unit make a transmitting power of the multiplexed QAM-modulated wave identical to that of another QAM method used on the same transmission line.

Setting the transmitting power at the same level as in the conventional method in this manner makes it possible to immediately use a multiplexed QAM-modulated wave according to the method of the invention in place of a modulated wave according to another QAM method using the same transmission line.

In particular, if a modulated wave having a smaller gain (hereinafter referred to as “auxiliary modulated wave”) is set sufficiently weaker than a modulated wave having a larger gain (hereinafter referred to as “main modulated wave”), the main modulated wave can be demodulated by using a conventional QAM demodulator as it is. This enables a practical form of transmission in which whereas data transmission that is compatible with the conventional method is performed by using a main modulated wave, another piece of data is transmitted by using an auxiliary modulated wave.

(4) It is preferable that the multiplexing QAM apparatus further include a frequency multiplexing unit that frequency-multiplexes a plurality of multiplexed QAM-modulated waves having different carrier frequencies.

Generated by multiplexing QAM-modulated waves having the same carrier frequency, a multiplexed QAM-modulated wave according to the method of the invention has a single-carrier feature. Therefore, a multiplexed QAM-modulated wave according to the method of the invention is far superior in enabling efficient use of a limited frequency band.

Taking advantage of this feature, plural multiplexed QAM-modulated waves may be frequency-multiplexed. This makes it possible to further increase the amount of data that can be transmitted at one time and to thereby realize even faster data transmission.

(5) A multiplexing QAM demodulation apparatus according to the invention is a multiplexing QAM demodulation apparatus which demodulates a reception signal of a multiplexed QAM-modulated wave transmitted from a multiplexing QAM apparatus and determines a plurality of differential-gain-multiplexed input data. This multiplexing QAM demodulation apparatus includes the following probability calculating unit and demodulation unit.

The probability calculating unit calculates probabilities that the reception signal corresponds to respective symbol positions, based on a symbol position variance caused by a transmission line.

The demodulation unit calculates an expectation value of each of the plurality of differential-gain-multiplexed input data based on the calculated probabilities and estimates the input data based on the expectation values.

(6) It is preferable that the demodulation unit first estimates input data having been given a larger modulated wave gain in multiplexing, and then estimates remaining input data while eliminating improbable symbol positions from the estimated input data.

This processing makes it possible to increase the accuracy of estimating remaining input data as well as to reduce the amount of calculation that is necessary for the estimation of the remaining input data.

(7) Another multiplexing QAM demodulation apparatus according to the invention is a multiplexing QAM demodulation apparatus which demodulates a reception signal of a multiplexed QAM-modulated wave transmitted from a multiplexing QAM apparatus and determines a plurality of differential-gain-multiplexed input data. This multiplexing QAM demodulation apparatus includes the following judgment unit.

The judgment unit estimates individual symbol positions which appear in the received multiplexed QAM-modulated wave, based on a characteristic of a transmission line, determines a most probable symbol position based on distances between the estimated individual symbol positions and a symbol position of the reception signal, and determines the plurality of input data from the determined symbol position.

(8) A further multiplexing QAM demodulation apparatus according to the invention is a multiplexing QAM demodulation apparatus which demodulates a reception signal of a multiplexed QAM-modulated wave transmitted from a multiplexing QAM apparatus and determines a plurality of differential-gain-multiplexed input data. This multiplexing QAM demodulation apparatus includes the following training unit.

The training unit receives a prescribed training signal that is transmitted from the multiplexing QAM apparatus during an initialization period of signal transmission, and determines, based on the training signal, by operating with the multiplexing QAM apparatus, at least one parameter among a QAM value of respective QAM-modulated waves to be differential-gain-multiplexed, a gain difference between the QAM-modulated waves, and a phase difference between the QAM-modulated waves so that a proper inter-symbol distance of the multiplexed QAM-modulated wave can be secured after the reception.

(9) A communication method according to the invention includes the steps of generating a multiplexed QAM-modulated wave using the above-described multiplexing QAM apparatus, and transmitting the generated multiplexed QAM-modulated wave to a communication destination.

### BRIEF DESCRIPTION OF THE DRAWINGS

The above and other objects of the present invention will easily be understood from the following description and accompanying drawings, wherein:

FIG. 1 shows an example of synthesis of a multiplexed QAM-modulated wave;

FIG. 2 shows another example of synthesis;

FIG. 3 shows a further example of synthesis;

FIG. 4 is a block diagram showing the configuration of a multiplexing QAM apparatus 11 according to an embodiment;

FIG. 5 is a block diagram showing the configuration of a multiplexing QAM modulation apparatus 12 according to the embodiment;

FIG. 6 illustrates calculation of conditional probabilities;

FIG. 7 illustrates calculation of an expectation value;

FIG. 8 is a flowchart showing the procedure of a training operation; and

FIG. 9 shows another demodulation process.

### BEST MODE FOR CARRYING OUT THE INVENTION

An embodiment of the present invention will be hereinafter described with reference to the drawings.

[Multiplexing QAM Apparatus]

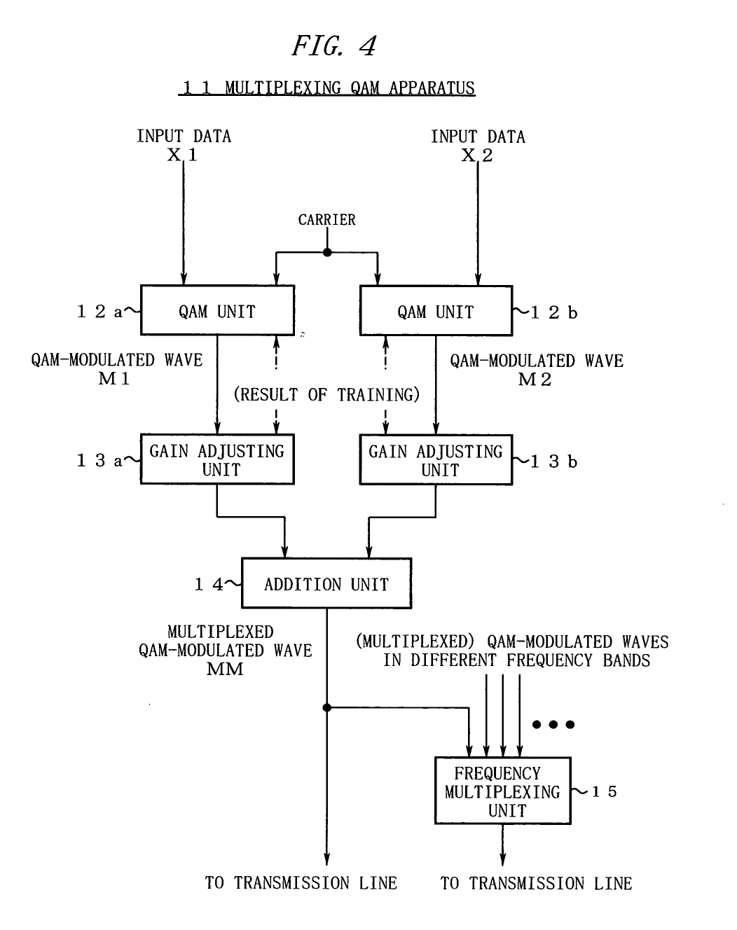

FIG. 4 is a block diagram showing the configuration of a multiplexing QAM apparatus 11 according to the embodiment.

As shown in FIG. 4, plural input data X1 and X2 are input to the multiplexing QAM apparatus 11. The input data X1 and X2 may be either independent data or data generated by dividing a single, original piece of data.

The input data X1 and X2 are input to respective QAM units 12a and 12b. Carriers having the same frequency are supplied to the QAM units 12a and 12b. The QAM units 12a and 12b QAM-modulate the input data X1 and X2 using the carriers having the same frequency and thereby generate plural QAM-modulated waves M1 and M2.

The generated QAM-modulated waves M1 and M2 are input to an addition unit 14 after being adjusted in gain difference by gain adjusting units 13a and 13b. The addition unit 14 generates a multiplexed QAM-modulated wave MM by combining (adding) the QAM-modulated waves M1 and M2 together.

In the above operation, it is appropriate to determine a gain difference so that symbol positions will not coincide with each other in a synthesized, multiplexed QAM-modulated wave MM.

A preferred example of a gain difference thus determined is such that the gain of the one QAM-modulated wave M1 is set at 0.995 (0.99 in terms of transmitting power) and the gain of the other QAM-modulated wave M2 is set at 0.1 (0.01 in terms of transmitting power) when the gain of a QAM-modulated wave obtained by a conventional method is used as a reference.

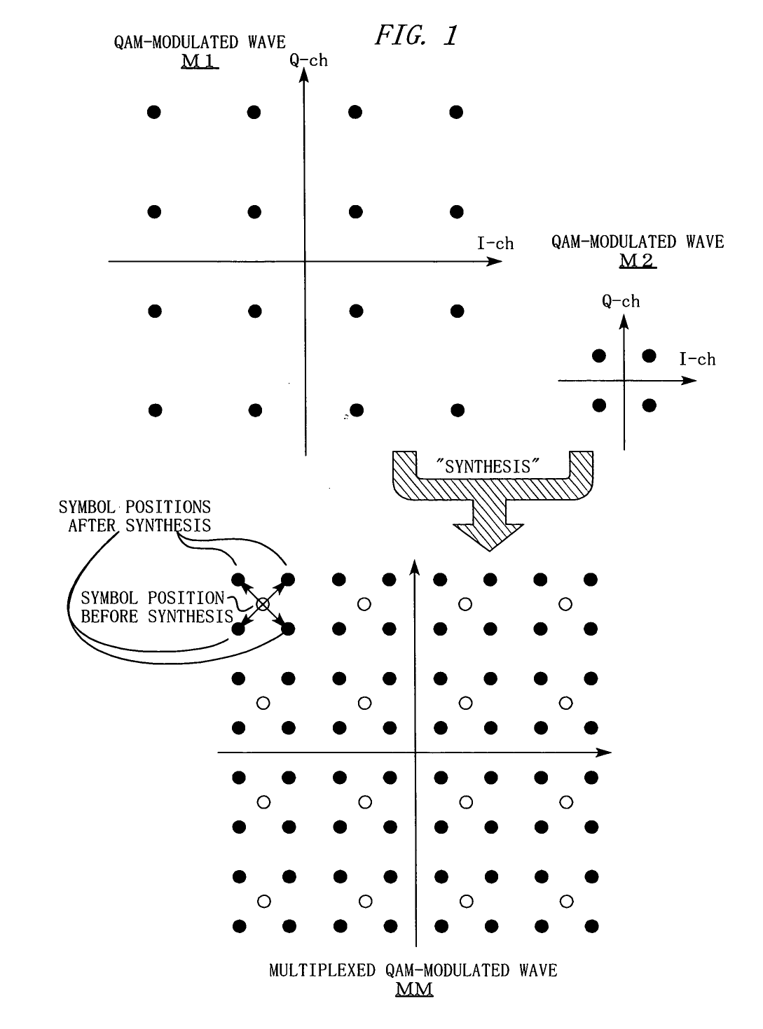

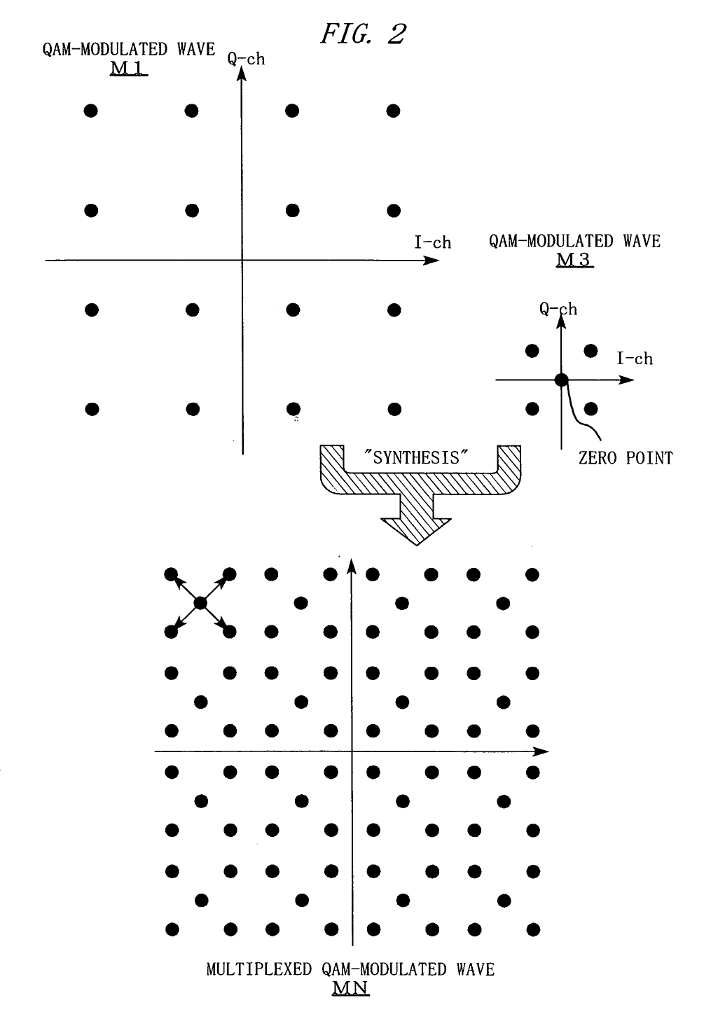

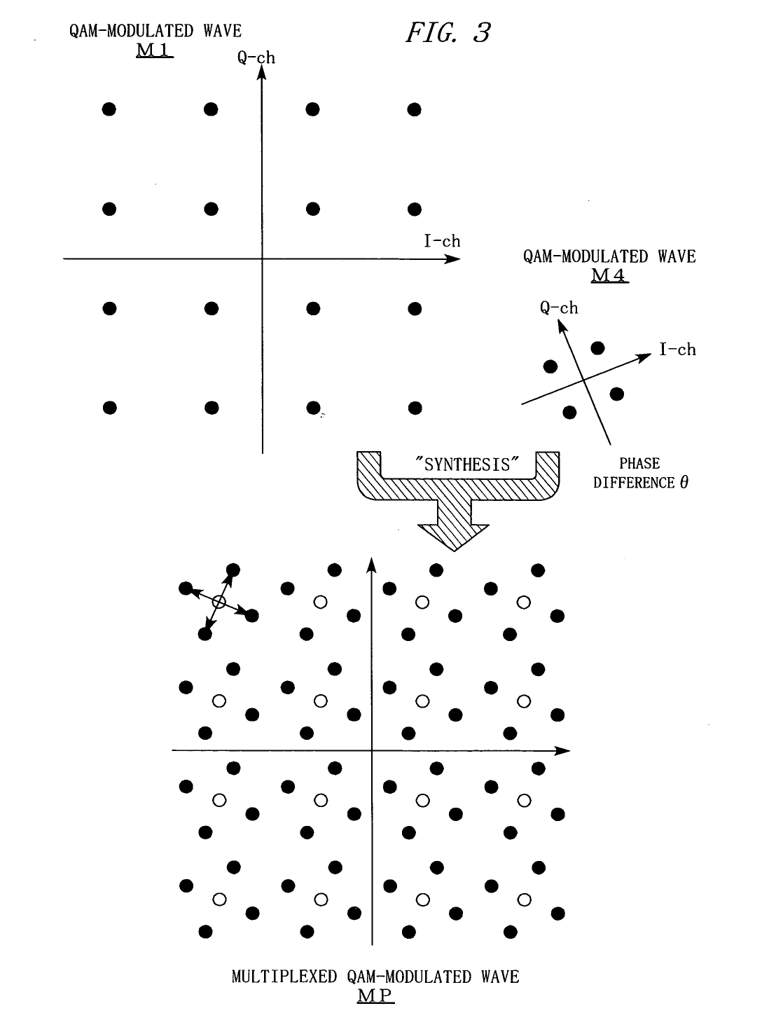

FIGS. 1 to 3 shows examples of synthesis of a multiplexed QAM-modulated wave MM. (The description has already been made with reference to FIGS. 1 to 3 in the “Disclosure of the Invention” section, a redundant description will not be made here.)

Actually, multiplexed QAM-modulated waves having of a greater variety of symbol position arrangements can be generated freely by changing the QAM values before synthesis, the gain difference before synthesis, the symbol position arrangements before synthesis, the phase difference before synthesis, or the like.

The addition unit 14 transmits the thus-generated multiplexed QAM-modulated wave MM to a multiplexing QAM demodulation apparatus 21 as a communication destination after making its transmitting power identical to the transmitting power of another QAM method used on the same transmission line.

Plural multiplexed QAM-modulated waves in different frequency bands may be frequency-multiplexed by using a frequency multiplexing unit 15.

[Multiplexing QAM Demodulation Apparatus]

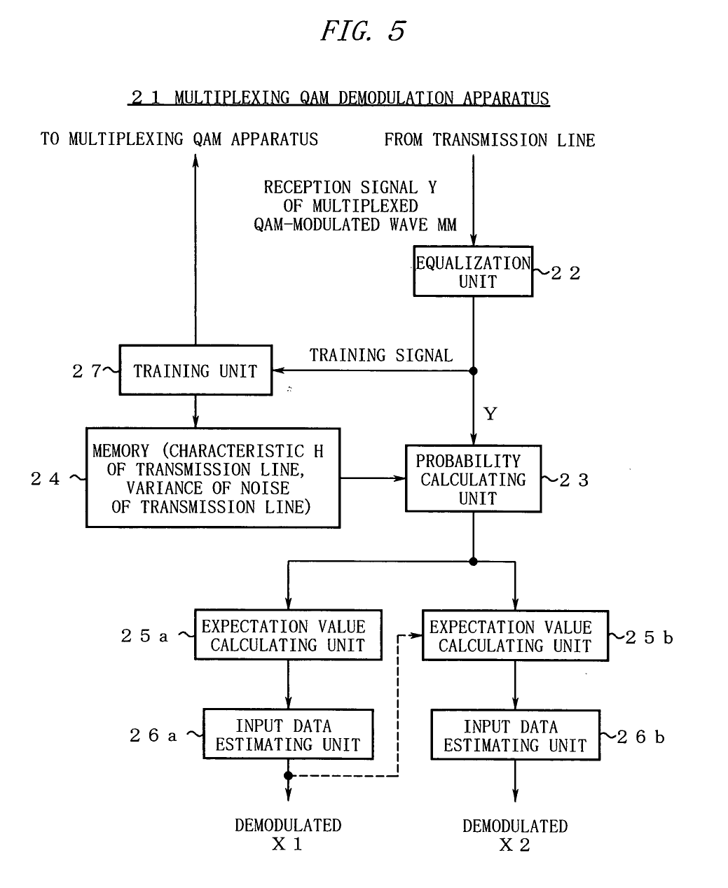

FIG. 5 is a block diagram showing the configuration of the multiplexing QAM demodulation apparatus 21 according to the embodiment.

As shown in FIG. 5, the multiplexing QAM demodulation apparatus 21 receives a reception signal Y of a multiplexed QAM-modulated wave MM via a transmission line. (Where the multiplexed QAM-modulated wave MM is one that was frequency-multiplexed on the transmission side, it is divided into individual multiplexed QAM-modulated waves using a frequency discriminating unit (not shown).)

The reception signal Y is input to an equalization unit 22, where variations in amplitude and phase that have occurred during the propagation through the transmission line are corrected.

Now, an equation representing an ideal reception signal Yo will be determined by assuming a case that no background noise exists on the transmission line.

First, the transmission line (including the equalization unit 22) is represented by H and the gains of the above-described gain adjusting units 13a and 13b are represented by G1 and G2, respectively. (Phases may be included in G1 and G2.)

The ideal reception signal Yo can be expressed by the following vector equation on the IQ constellation:

$$\begin{matrix}\begin{matrix} Yo = [ X1 & X2 ] [ \begin{matrix}H1 \\ H2\end{matrix} ]\end{matrix} \\ ≡ Xh\end{matrix} \qquad ( 1 )$$

where X1 and X2 are vectors, on the IQ constellation, of QAM-modulated waves M1 and M2 before synthesis and H1 and H2 correspond to (G1·H) and (G2·H), respectively.

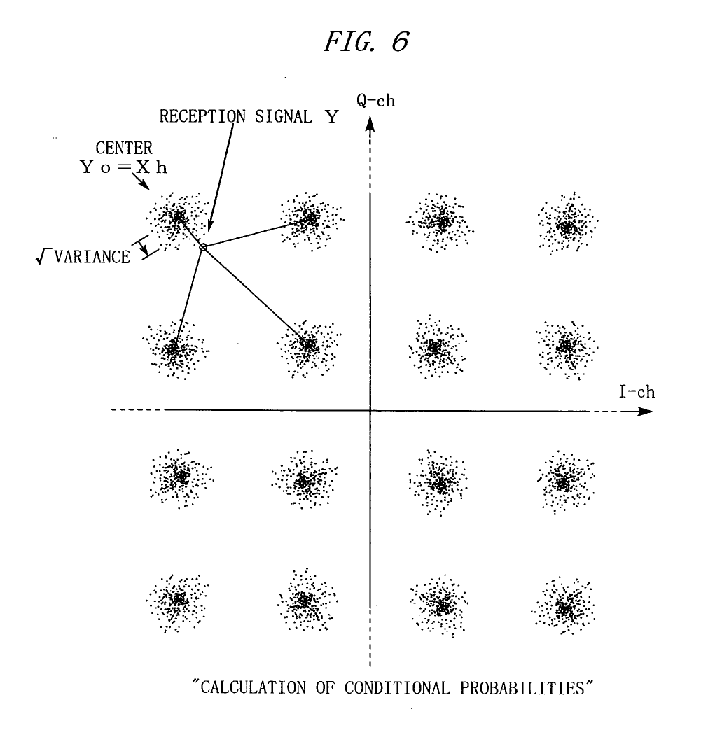

The ideal reception signal Yo=Xh corresponds to the center of each symbol position of the reception signal Y shown in FIG. 6. The actual reception signal Y is a signal that is obtained by adding background noise of the transmission line to the ideal reception signal Yo=Xh. Therefore, a probability f_{Y/X} that the transmission signal X=(X1, X2) becomes the reception signal Y is given by

$${f}_{Y / X} = c exp [ \frac{- {‖ Y - Xh ‖}^{2}}{2 {σ}^{2}} ] \qquad ( 2 )$$

where σ² is the variance of the background noise on the IQ constellation, c is the normalization coefficient, and ∥Y−Xh∥ corresponds to the inter-symbol distance between the center Xh of each symbol position and the reception signal Y.

The characteristic h of the transmission line and the variance σ² of the background noise of the transmission line that are necessary for calculation of Equation (2) are recorded in a memory 24 of the multiplexing QAM demodulation apparatus 21. These values are determined by a training operation (described later).

A probability calculating unit 23 reads the characteristic h the variance σ² from the memory 24 and calculates, according to Equation (2), conditional probabilities f_{Y/X} that all possible transmission signals X=(X1, X2) become the reception signal Y.

The values of the thus-calculated conditional probabilities are input to each of expectation value calculating units 25a and 25b.

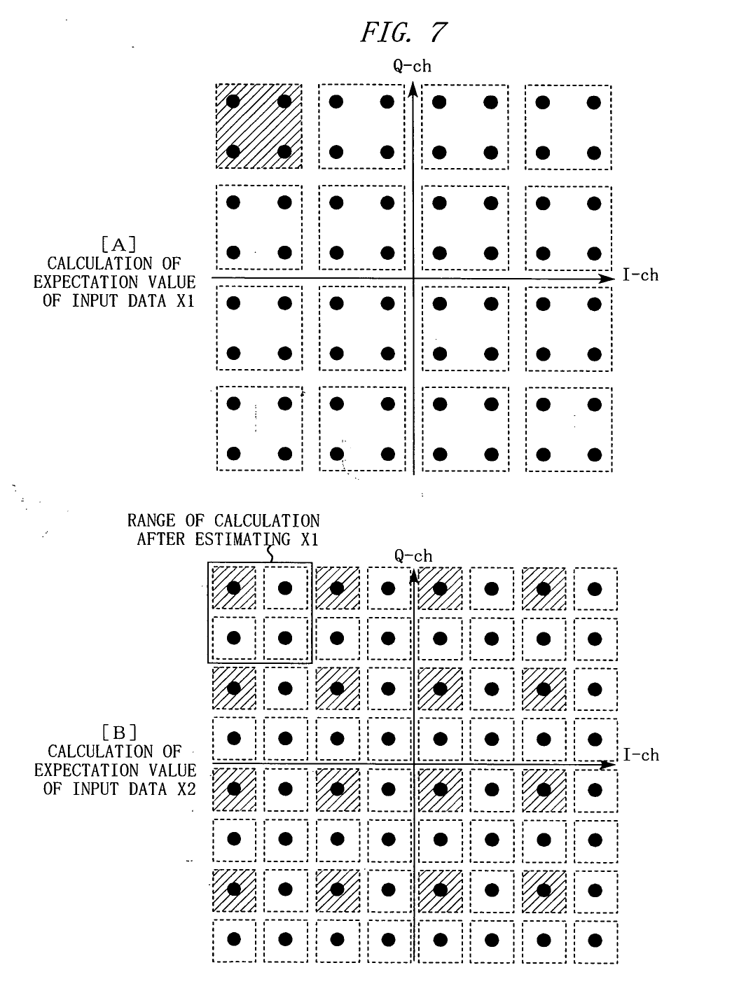

Ranges enclosed by broken lines in FIG. 7[A] are ranges obtained by grouping the symbol positions so that in each range the input data X1 having the larger modulated wave gain takes the same value. The probability that the reception signal Y corresponds to input data X1 can be determined by adding conditional probabilities f_{Y/X} in the broken-line range. An expectation value E(X1) of the input data X1 can be determined by calculating the sum of products of the input data X1 and the probabilities.

That is, the expectation value E(X1) of the input data X1 is given by

$$\begin{matrix}E ( X1 ) = \frac{ \sum ( X1 , X2 ) \cdot {f}_{Y / X}}{\sum {f}_{Y / X}} \\ = \frac{\sum {f}_{Y / X}}{\sum {f}_{Y / X}}\end{matrix} \qquad ( 3 )$$

The expectation value calculating unit 25a calculates the expectation value E(X1) according to Equation (3).

An input data estimating unit 26a determines a symbol position that is closest to the expectation value E(X1) on the IQ constellation of the QAM-modulated wave M1 before synthesis and outputs, as a demodulation result, input data X1 corresponding to that symbol position.

The expectation value calculating unit 25b acquires the demodulation result of the input data X1. Usually, symbol positions where the input data X2 takes the same value are spread widely as indicated by hatched ranges in FIG. 7[B] because they are shifted greatly by the input data X1 having the large modulated wave gain. Therefore, errors tend to be mixed into an expectation value E(X2) of input data X2.

In view of this, after replacing conditional probabilities f_{Y/X} of improbable symbol positions with zero based on the demodulation result of the input data X1, the expectation value calculating unit 25b calculates

$$\begin{matrix}E ( X2 ) = \frac{ \sum ( X1 , X2 ) \cdot {f}_{Y / X}}{\sum {f}_{Y / X}} \\ = \frac{\sum X \cdot {f}_{Y / X}}{\sum {f}_{Y / X}}\end{matrix} \qquad ( 4 )$$

A more correct expectation value E(X2) can be obtained because in calculating it the range of calculation is restricted to the range enclosed by a solid line in FIG. 7[B].

An input data estimating unit 26b determines a symbol position that is closest to the expectation value E(X2) on the IQ constellation of the QAM-modulated wave M2 before synthesis and outputs, as a demodulation result, input data X2 corresponding to that symbol position.

The multiplexing QAM demodulation apparatus 21 can obtain demodulation results of input data X1 and X2 by processing a reception signal Y according to the above series of steps.

[Training Operation]

Next, a training operation that is performed during an initialization period of signal transmission will be described.

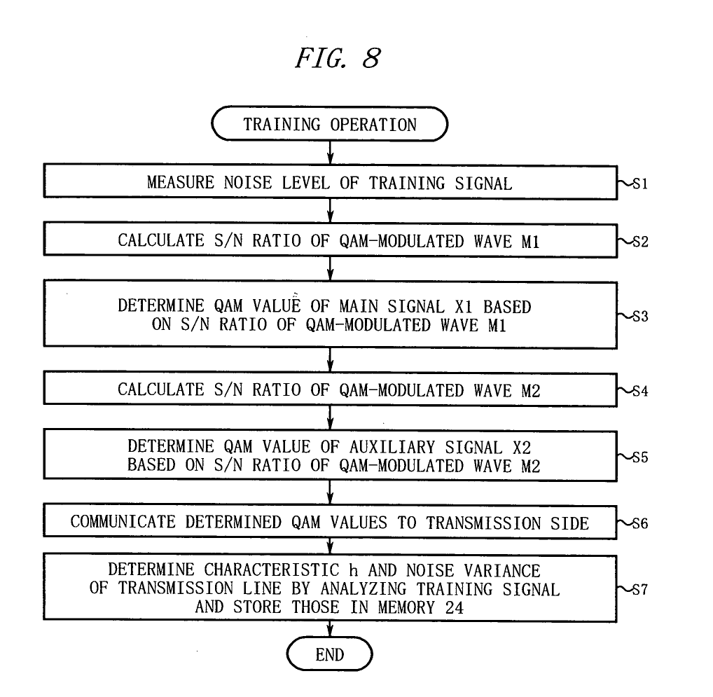

FIG. 8 is a flowchart showing the procedure of the training operation.

(Step S1) The multiplexing QAM apparatus 11 transmits a prescribed training signal to the multiplexing QAM demodulation apparatus 21 and the multiplexing QAM demodulation apparatus 21 receives the training signal. A training unit 27 of the multiplexing QAM demodulation apparatus 21 determines a noise level of a transmission line based on a reception signal of the training signal.

(Step S2) The training unit 27 calculates an S/N ratio of a QAM-modulated wave M1 based on the noise level of the transmission line and a transmitting power of the QAM-modulated wave M1.

(Step S3) The training unit 27 determines a QAM value of the QAM-modulated wave M1 by referring to a correspondence table based on the S/N ratio of the QAM-modulated wave M1. The correspondence table is such that optimum QAM values obtained in advance by an experiment or a theoretical calculation are stored so as to be correlated with S/N ratios of the QAM-modulated wave M1. A method using a QAM value determination algorithm may be employed instead of the method using a correspondence table.

(Step S4) The training unit 27 calculates an S/N ratio of a QAM-modulated wave M2 based on the noise level of the transmission line and a transmitting power of the QAM-modulated wave M2.

(Step S5) The training unit 27 determines a QAM value of the QAM-modulated wave M2 by referring to a correspondence table based on the S/N ratio of the QAM-modulated wave M2. The correspondence table is such that optimum QAM values obtained in advance by an experiment or a theoretical calculation are stored so as to be correlated with S/N ratios of the QAM-modulated wave M2. A method using a QAM value determination algorithm may be employed instead of the method using a correspondence table.

Determining QAM values in the above manner makes it possible to secure, after reception, a proper inter-symbol distance of a multiplexed QAM-modulated wave. Where the noise level of the transmission line is insufficient for the method of the invention, the QAM value of the QAM-modulated wave M2 becomes zero. In this case, the transmitting power of the QAM-modulated wave M1 is returned to the conventional level and signal transmission is performed in the conventional manner using only the QAM-modulated wave M1.

(Step S6) The training unit 27 communicates the determined QAM values to the multiplexing QAM apparatus 11.

(Step S7) The training unit 27 analyzes the symbol position arrangement of the received training signal and thereby determines a characteristic h of the transmission line and a symbol position variance σ² caused by the transmission line. The training unit 27 stores the calculated values in the memory 24. Alternatively, a variance σ² for each symbol position may be estimated from the noise level of the transmission line that was determined at step S1.

The training operation that is performed during the initialization period is thus completed by the above operation.

[Corresponding Relationship with the Invention]

A corresponding relationship between the above embodiment and the claims will be described below. This corresponding relationship is just one interpretation for reference and should not be used for limiting the scope of the invention unduly.

The QAM unit in the claims corresponds to the QAM units 12a and 12b.

The modulated waves combining unit in the claims corresponds to the gain adjusting units 13a and 13b and the addition unit 14.

The frequency multiplexing unit in the claims corresponds to the frequency multiplexing unit 15.

The probability calculating unit in the claims corresponds to the probability calculating unit 23.

The demodulation unit in the claims corresponds to expectation value calculating units 25a and 25b and the input data estimating units 26a and 26b.

The training unit in the claims corresponds to the training unit 27.

[Advantages etc. of Embodiment]

As described above, according to this embodiment, since plural QAM-modulated waves having the same carrier frequency are combined together after being given a gain difference, a further increased level of multi-valuing of a QAM-modulated wave can be realized.

Further, a symbol position arrangement as cannot be realized conventionally can be realized with a high degree of freedom by adjusting the gain difference before synthesis, individual QAM values before synthesis, the phase difference before synthesis, or the like.

According to this embodiment, since the transmitting power of a multiplexed QAM-modulated wave is set at the same level as in the conventional method, a multiplexed QAM-modulated wave according to the method of the invention can be used immediately in place of a modulated wave according to another QAM method using the same transmission line.

Generated by multiplexing QAM-modulated waves having the same carrier frequency, a multiplexed QAM-modulated wave according to the method of the invention has a single-carrier feature. Therefore, a multiplexed QAM-modulated wave according to the method of the invention is far superior in enabling efficient use of a limited frequency band. Taking advantage of this feature, the amount of data that can be transmitted at one time can be increased by frequency-multiplexing plural multiplexed QAM-modulated waves.

In this embodiment, input data X1 having a larger modulated wave gain is estimated first by demodulation and the estimation range of remaining input data X2 is restricted based on the demodulation result of the input data X1. This reduces the amount of calculation that is necessary for the estimation of the input data X2 while increasing the accuracy of estimation of the input data X2.

Further, in this embodiment, a training operation is performed during an initialization period, whereby QAM values of QAM-modulated waves M1 and M2 before synthesis are determined properly. Therefore, a proper inter-symbol distance of a multiplexed QAM-modulated wave can be secured after reception in accordance with a transmission line state.

[Supplements to Embodiment]

Supplements to the embodiment will be described below.

The above-described embodiment is directed to the case of combining two QAM-modulated waves together. However, the invention is not limited to such a case. For example, three or more QAM-modulated waves may be combined together. Also in this case, it is possible to prevent symbol positions of a multiplexed QAM-modulated wave from coincide with each other by giving gain differences to the plural QAM-modulated waves.

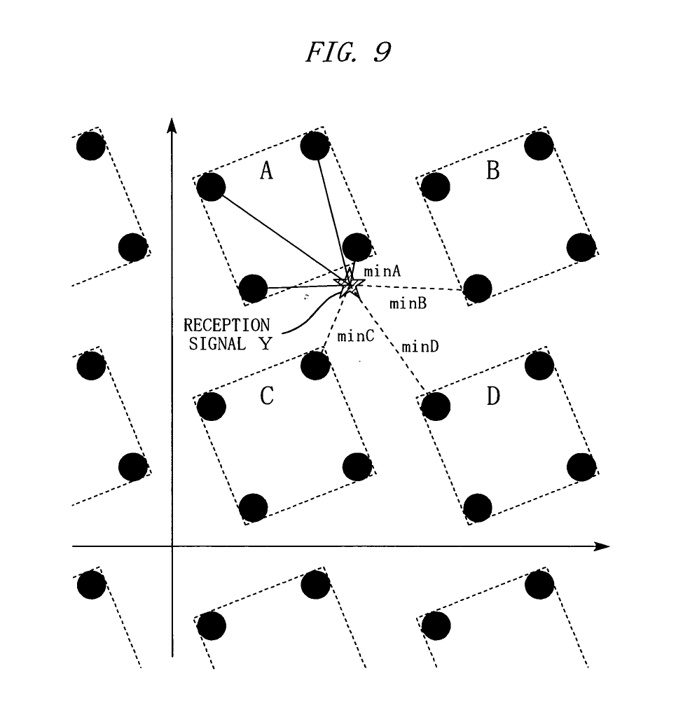

In the above embodiment, highly accurate demodulation results are obtained by closely calculating an expectation value of input data. However, the invention is not limited to such a case. For example, as shown in FIG. 9, input data X1 and X2 may be determined directly by determining a symbol position that is closest to a reception signal Y in a symbol position arrangement of an ideal reception signal Yo of a multiplexed QAM-modulated wave and determining the input data X1 and X2 as corresponding to that symbol position (corresponds to claim 7).

This configuration may also be such that input data X1 having a larger modulated wave gain is determined first and remaining input data X2 is determined by determining a symbol position closest to a reception signal Y after restricting the range of existence (indicated by symbol A in FIG. 9) of a symbol position based on the input data X1.

In the above embodiment, QAM values before synthesis are determined by a training operation. However, the invention is not limited to such a case. A gain difference before synthesis, a phase difference before synthesis, or the like may be determined by a training operation. It is appropriate to determine each of these parameters so that a proper symbol position distance of a multiplexed QAM-modulated wave is secured after reception.

In the above embodiment, in a training operation, a noise level of a transmission line is detected and S/N ratios of QAM-modulated waves M1 and M2 are determined from the noise level. However, the invention is not limited to such a case. For example, in a training operation, S/N ratios of QAM-modulated waves M1 and M2 may be determined directly by transmitting the QAM-modulated waves M1 and M2, respectively. Alternatively, in a training operation, an S/N ratio of a gain-multiplexed QAM-modulated wave may be determined by transmitting the gain-multiplexed QAM-modulated wave. S/N ratios of separated QAM-modulated waves M1 and M2 may be determined based on the S/N ratio of the gain-multiplexed QAM-modulated wave. As a further alternative, in a training operation, an S/N ratio is determining by transmitting a conventional QAM-modulated wave and calculating S/N ratios of respective QAM-modulated waves M1 and M2 based on the determined S/N ratio and a transmitting power of the QAM-modulated waves M1 and M2.

The invention can be implemented in other various forms without departing from the spirit and essential features of the invention. Therefore, the above embodiment is just an example in every point and the invention should not be construed restrictively in connection with the embodiment. The scope of the invention should be defined by the claims and is not limited by the specification body at all. Further, all modifications and changes that are within the range of equivalence of the claims are covered by the invention.

### INDUSTRIAL APPLICABILITY

As described above, the multiplexing QAM apparatus according to the invention generates a multiplexed QAM-modulated wave in which symbol positions can be separated from each other by combining plural QAM-modulated waves having the same carrier frequency after giving a gain difference to those. Having a single carrier feature, the multiplexed QAM-modulated wave is superior in enabling multi-valuing that utilizes a gain difference while efficiently using a limited frequency band.

This multiplexed QAM-modulated wave is far superior in easily enabling a variety of symbol position arrangements by adjusting the gain difference before synthesis, the symbol position arrangements before synthesis, the phase difference before synthesis, or the like.

In one multiplexing QAM demodulation apparatus according to the invention, probabilities that a reception signal corresponds to individual symbol positions are determined based on a symbol position variance that is caused by propagation through a transmission line. An expectation value of each piece of input data can be calculated by calculating the sum of products of the probabilities of the respective symbol positions and values of input data indicated by the respective symbol positions. Input data to be estimated is determined based on the expectation value. This operation enables demodulation by properly separating differential-gain-multiplexed input data from each other.

It is preferable that the multiplexing QAM demodulation apparatus first estimate input data that was given a larger modulated wave gain in multiplexing.

Usually, symbol positions corresponding to input data that was given a larger modulated wave gain in multiplexing are concentrated at local positions on the IQ constellation (see FIG. 7[A], for example). Therefore, estimating such input data first makes it possible to obtain highly accurate partial demodulation results first.

On the other hand, symbol positions of remaining input data are dispersed (see FIG. 7[B], for example) because they are shifted greatly by the input data having the larger modulated wave gain. However, the range where a symbol position can exist can be restricted to a narrow range by using the already estimated input data having the larger modulated wave gain. This symbol position restriction makes it possible to estimate the remaining input data properly and to thereby obtain a more accurate demodulation result.

In another multiplexing QAM demodulation apparatus according to the invention, individual symbol positions of a reception signal are estimated in advance based on a symbol position arrangement of a multiplexed QAM-modulated wave and a characteristic of a transmission line. The multiplexed QAM-modulated wave is demodulated by determining a most probable symbol position based on distances between the individual estimated symbol positions and a symbol position of the multiplexed QAM-modulated wave. In this demodulation method, estimating individual symbol positions of a reception signal in advance makes it possible to immediately identify a symbol position of a reception signal merely by determining, through comparison, an estimated symbol position that is closest to the symbol positions of the reception signal. This makes it possible to demodulate a multiplexed QAM-modulated wave quickly by a small amount of calculation.

In a further multiplexing QAM demodulation apparatus according to the invention, a parameter of a multiplexed QAM-modulated wave (at least one of QAM values of QAM-modulated waves to be differential-gain-multiplexed, a gain difference between the QAM-modulated waves, and a phase difference between the QAM-modulated waves) is determined by a training during an initialization period.

As described above, the degree of freedom of the symbol position arrangement of a multiplexed QAM-modulated wave is very high. Therefore, in the above parameter training selection can be made from a variety of symbol position arrangements, which makes it possible to set a symbol position arrangement that is more suitable for a transmission line state from a wide choice of arrangements.

The communication method according to the invention is a communication method which generates a differential-gain-multiplexed QAM-modulated wave using the above-described multiplexing QAM apparatus, and transmits the generated multiplexed QAM-modulated wave to a transmission line.

This communication method realizes signal transmission using a multiplexed QAM-modulated wave having the above-described advantages.

1. A multiplexing QAM (Quadrature Amplitude Modulation) apparatus comprising:
a QAM unit that generates a plurality of QAM-modulated waves by QAM-modulating a plurality of input data with a common carrier frequency; and
a modulated waves combining unit that generates a multiplexed QAM-modulated wave by combining said plurality of QAM-modulated waves together, wherein
said modulated waves combining unit gives a gain difference to said plurality of QAM-modulated waves to be combined together, so that symbol positions of said multiplexed QAM-modulated wave combined do not coincide with each other.

2. The multiplexing QAM apparatus according to claim 1, wherein said QAM unit gives a phase difference to at least two of said QAM-modulated waves.

3. The multiplexing QAM apparatus according to claim 1, wherein said modulated waves combining unit makes a transmitting power of said multiplexed QAM-modulated wave identical to that of another QAM method used on a same transmission line.

4. The multiplexing QAM apparatus according to claim 1, further comprising a frequency multiplexing unit that frequency-multiplexes a plurality of multiplexed QAM-modulated waves having different carrier frequencies.

5. A multiplexing QAM demodulation apparatus which demodulates a reception signal of a multiplexed QAM-modulated wave transmitted from a multiplexing QAM apparatus and determines a plurality of differential-gain-multiplexed input data, comprising:
a probability calculating unit that calculates probabilities that said reception signal corresponds to respective symbol positions, based on variance of symbol positions caused by a transmission line; and
a demodulation unit that calculates an expectation value of each of said plurality of differential-gain-multiplexed input data, based on said probabilities that said reception signal corresponds to said respective symbol positions, and estimates said input data based on said expectation value of said input data.

6. The multiplexing QAM demodulation apparatus according to claim 5, wherein said demodulation unit first estimates said input data having been given a larger modulated wave gain in multiplexing, and then estimates remaining input data while eliminating improbable symbol positions from the estimated input data.

7. A multiplexing QAM demodulation apparatus which demodulates a reception signal of a multiplexed QAM-modulated wave transmitted from a multiplexing QAM apparatus and determines a plurality of differential-gain-multiplexed input data, comprising:
a judgment unit that estimates individual symbol positions which appear in the received multiplexed QAM-modulated wave based on both a symbol position arrangement of said multiplexed QAM-modulated wave and a characteristic of a transmission line, determines a most probable symbol position based on distances between the estimated individual symbol positions and a symbol position of said reception signal, and then determines said plurality of input data from the determined symbol position.

8. A multiplexing QAM demodulation apparatus which demodulates a reception signal of a multiplexed QAM-modulated wave transmitted from a multiplexing QAM apparatus and determines a plurality of differential-gain-multiplexed input data, comprising:
a training unit that receives a prescribed training signal transmitted from said multiplexing QAM apparatus during an initialization period of signal transmission, and determines, based on said training signal, by operating with said multiplexing QAM apparatus, at least one parameter among: a QAM value of respective QAM-modulated waves to be differential-gain-multiplexed into said multiplexed QAM-modulated wave; a gain difference between said QAM-modulated waves; and a phase difference between said QAM-modulated waves, so that a proper inter-symbol distance of said multiplexed QAM-modulated wave can be secured after the reception.

9. A communication method comprising the steps of:
generating a multiplexed QAM-modulated wave using a multiplexing QAM apparatus; and
transmitting the generated multiplexed QAM-modulated wave to a communication destination.
